(19) United States
(12) Patent Application Publication
(10) Pub. No.: US 2015/0367452 A1
(43) Pub. Date: Dec. 24, 2015

(54) SHADOW MASKS AND METHODS FOR THEIR PREPARATION AND USE

(71) Applicant: Indian Institute of Technology Kanpur, Kanpur (IN)

(72) Inventors: Govind Dayal Singh, Allahabad (IN); Ramakrishna Subramaniam Anantha, Kanpur (IN)

(21) Appl. No.: 14/737,409

(22) Filed: Jun. 11, 2015

(30) Foreign Application Priority Data
Jun. 24, 2014 (IN) 1685/DEL/2014

(51) Int. Cl. B23K 26/382; C23C 14/34; B23K 26/402; B29C 71/02; C23C 16/04; C23C 14/04

(52) U.S. Cl. CPC B23K 26/382; C23C 16/042; C23C 14/042; B23K 26/402; B29C 71/02; C23C 14/34; B29C 2071/022; B29K 2079/08

(57) ABSTRACT

A method of forming a shadow mask is provided. The method includes annealing at least one polymeric sheet to form at least one annealed polymeric sheet. The method also includes transferring a pattern from a primary mask to the annealed polymeric sheet using laser micromachining to form the shadow mask.

### CROSS-REFERENCE TO RELATED APPLICATION

This application claims priority under 35 U.S.C. §119(a) of India Application No. 1685/DEL/2014 filed on Jun. 24, 2014. The India Application is hereby incorporated by reference in its entirety.

### BACKGROUND

Several fabrication techniques are used for large scale patterning of metallic thin films used in integrated circuits. In particular, patterning of metallic films at micro and nanoscale is used for making components such as interconnects on electronic boards and chips, and for microwaves and meta-material applications.

Existing fabrication techniques such as electron-beam lithography, focused ion beam milling, micro-imprint lithography, direct laser writing are slow, expensive and might not be suitable for patterning at micrometer scale. Such techniques are unsuitable for mass production, and particularly for large area structures having features with sizes in micrometer ranges.

Other existing fabrication techniques such as photolithography, and interference optical lithography include large number of fabrication steps, are time consuming and expensive. Shadow or stencil lithography techniques involve applying a patterned mask over a substrate and depositing materials by evaporation or deposition through openings in the mask. However, the masks can only be used once for deposition as they can be etched away after deposition of the material.

### SUMMARY

The foregoing summary is illustrative only and is not intended to be in any way limiting. In addition to the illustrative aspects, embodiments, and features described above, further aspects, embodiments, and features will become apparent by reference to the drawings and the following detailed description.

Briefly, in accordance with one aspect, a method of forming a shadow mask is provided. The method includes annealing at least one polymeric sheet to form at least one annealed polymeric sheet. The method also includes transferring a pattern from a primary mask to the annealed polymeric sheet using laser micromachining to form the shadow mask.

In accordance with another aspect, a method of forming a pattern on a substrate is provided. The method includes transferring a pattern from a primary mask to an annealed polymeric sheet using laser micromachining to form a shadow mask having a plurality of apertures. The method also includes mounting the shadow mask on a first surface of the substrate and depositing a material on the first surface of the substrate through the plurality of apertures of the shadow mask to form the pattern on the substrate.

In accordance with another aspect, a shadow mask is provided. The shadow mask includes an annealed polymeric sheet. The shadow mask also includes a plurality of apertures formed in the annealed polymeric sheet to deposit a material on a substrate through the plurality of apertures and to form a desired pattern of the material on the substrate.

In accordance with another aspect, an assembly is provided. The assembly includes a substrate. The assembly further includes a shadow mask disposed on a first surface of the substrate. The shadow mask includes an annealed polymeric sheet having a plurality of apertures formed in the annealed polymeric sheet.

In accordance with another aspect, an assembly is provided. The assembly includes a substrate and a shadow mask disposed on a first surface of the substrate. The shadow mask includes an annealed polymeric sheet having a plurality of apertures formed in the annealed polymeric sheet. The assembly further includes a material disposed on the shadow mask. The shadow mask is configured to deposit the material on the substrate through the plurality of apertures to form a desired pattern of the material on the substrate.

### BRIEF DESCRIPTION OF THE FIGURES

FIG. 1 is an example flow diagram of an embodiment of a method of forming a shadow mask.

FIG. 2 is an example flow diagram of an embodiment of a method of forming a pattern on a substrate.

FIG. 3 illustrates an example shadow mask such as formed using the process of FIG. 1.

FIG. 4 illustrates a transmission optical image of the shadow mask.

FIG. 5 illustrates an optical microscope transmission image of gold deposited through the shadow mask of Example 1.

FIG. 6 illustrates a transmission optical microscope image of the shadow mask after first and fourth use of forming the pattern on substrate.

FIG. 7 is an example optical microscope image of reflectance from the shadow mask after fourth use of forming the pattern on substrate.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

It will also be understood that any compound, material or substance which is expressly or implicitly disclosed in the specification and/or recited in a claim as belonging to a group or structurally, compositionally and/or functionally related compounds, materials or substances, includes individual representatives of the group and all combinations thereof While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups.

Some embodiments are generally directed to techniques of forming shadow masks that may be used to deposit a material on a substrate through a plurality of features formed on the shadow mask. The present technique provides a method for fabricating high quality shadow masks with features having a variety of shapes and sizes. Moreover, the techniques are used in forming re-useable shadow masks for deposition of materials through features having sizes in micrometer range. The shadow masks described herein are formed by dry laser micromachining process.

The present technique facilitates fabrication of shadow masks having micrometer scale features. The technique allows for rapid mass production of laser micromachined shadow masks that can be used for high aspect ratio and multi-layer micro patterning of substrates for various applications. The shadow masks formed using the present techniques are reusable and are cost-effective. Moreover, the technique can be used for large area patterning of thin metallic films. The technique can be suitably used for etching and implantation of sub micrometer structures using ion beam and plasma techniques.

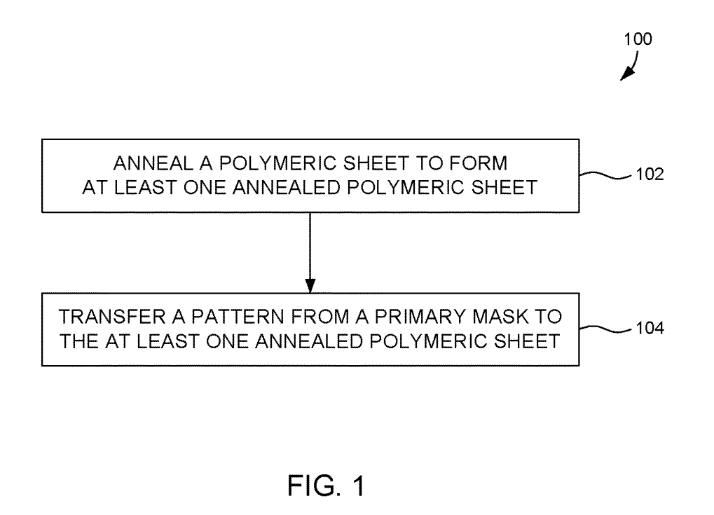

Referring now to FIG. 1, an example flow diagram 100 of an embodiment of a method of forming a shadow mask is illustrated. At block 102, a polymeric sheet is annealed to form at least one annealed polymeric sheet. In some examples, the polymeric sheet is heated to a temperature of about 100 centigrade (° C.) to about 200° C. to form at least one annealed polymeric sheet. Specific examples of the temperature include about 100° C., about 120° C., about 140° C., about 160° C., about 180° C., about 200° C., and ranges between any two of these values (including endpoints). In some examples, the at least one annealed polymeric sheet has a thickness of about 5 micrometers (μm) to about 15 μm. Specific examples of the thickness include about 5 μm, about 7 μm, about 9 μm, about 11 μm, about 13 μm, about 15 μm, and ranges between any two of these values (including endpoints). In one example, the annealed polymeric sheet has a thickness of about 12 μm.

In one example, the polymeric sheet includes polyimide. In some examples, the polymeric sheet includes polyethylene, polytetrafluoroethylene (PTFE), or combinations thereof.

At block 104, a pattern is transferred from a primary mask to the at least one annealed polymeric sheet using laser micromachining to form the shadow mask. In this embodiment, transferring the pattern includes forming a plurality of features on the annealed polymeric sheet. In some examples, the plurality of features include one or more apertures. The one or more apertures can generally be of any shape. Example shapes include circular, square, rectangular, complex, or combinations thereof. In some examples, the plurality of features have a radius of curvature of about 0.5 μm to about 1 μm. Specific examples of the radius of curvature include about 0.5 μm, about 0.6 μm, about 0.7 μm, about 0.8 μm, about 0.9 μm, about 1 μm, and ranges between any two of these values (including endpoints).

In some examples, the plurality of features have a size of about 1 μm to about 100 μm. Specific examples of the size include about 1 μm, about 10 μm, about 20 μm, about 40 μm, about 50 μm, about 60 μm, about 80 μm, about 100 μm, and ranges between any two of these values (including endpoints).

In some embodiments, the surface of the annealed polymeric sheet is laser machined using a laser emitting radiation with a wavelength of one of about 356 nanometers (nm), about 337 nm, about 308 nm, about 266 nm, about 248 nm, and about 193 nm.

In some embodiments, about 25 laser pulses are used to laser machine apertures through the annealed polymeric sheet. Here, the number of laser pulses is determined by the material and thickness of the sheet.

In one example, apertures through the annealed polymeric sheet having a thickness of about 12 μm are laser machined with about 25 laser pulses. Moreover, the laser pulses have a frequency of about 1 Hertz (Hz) to about 100 Hz. Specific examples of the frequency include about 1 Hz, about 10 Hz, about 20 Hz, about 40 Hz, about 50 Hz, about 60 Hz, about 80 Hz, about 100 Hz, and ranges between any two of these values (including endpoints).

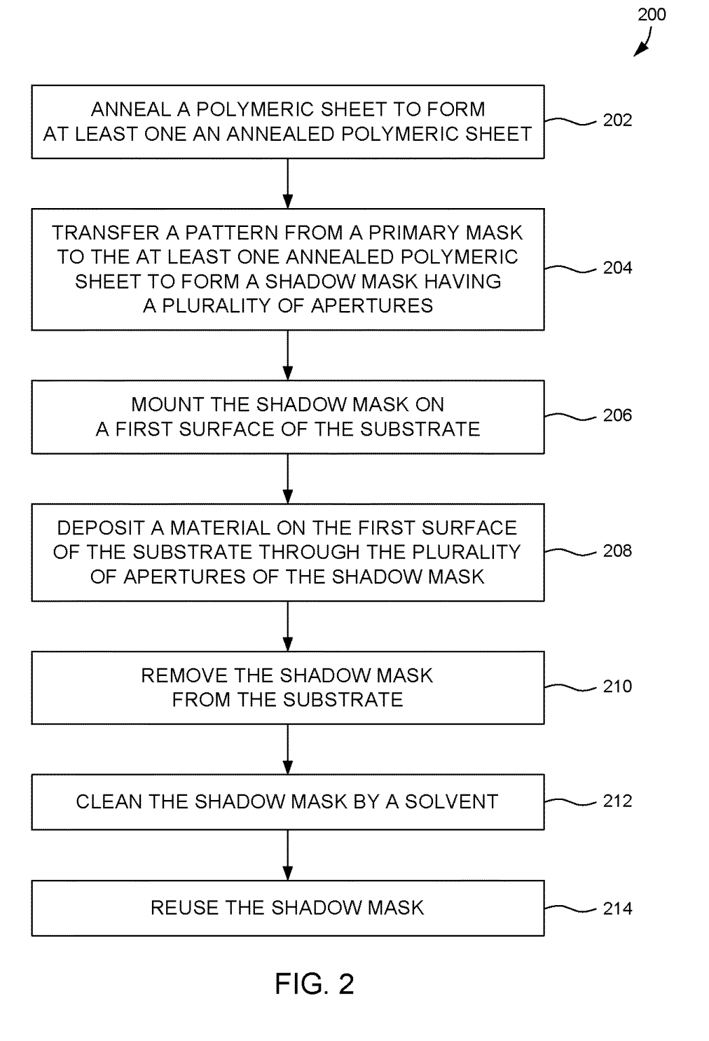

The shadow mask formed using the process of FIG. 1 can be used to deposit a variety of materials on a substrate. In FIG. 2, an example flow diagram 200 of an embodiment of a method of forming a pattern on a substrate is illustrated. At block 202, a polymeric sheet is annealed to form at least one annealed polymeric sheet. In some examples, the polymeric sheet is heated to a temperature of about 100 centigrade (° C.) to about 200° C. to form the at least one annealed polymeric sheet. Specific examples of the temperature include about 100° C., about 120° C., about 140° C., about 160° C., about 180° C., about 200° C., and ranges between any two of these values (including endpoints).

In one example, the polymeric sheet includes polyimide. In some examples, the polymeric sheet includes polyethylene, polytetrafluoroethylene (PTFE), or combinations thereof.

At block 204, a pattern from a primary mask is transferred to the at least one annealed polymeric sheet using laser micromachining to form a shadow mask having a plurality of apertures. The one or more apertures can generally be of any shape. Example shapes include circular, square, rectangular, complex, or combinations thereof. In some examples, the plurality of features have a radius of curvature of about 0.5 μm to about 1 μm. Specific examples of the radius of curvature include about 0.5 μm, about 0.6 μm, about 0.7 μm, about 0.8 μm, about 0.9 μm, about 1 μm, and ranges between any two of these values (including endpoints).

At block 206, the shadow mask is mounted on a first surface of the substrate. The substrate can be formed of any suitable material. In some examples, the substrate includes glass, silicon, aluminum, steel, silicon dioxide (SiO₂), aluminum oxide (Al₂O₃), zinc sulfide (ZnS), zinc selenide (ZnSe), teflon, or combinations thereof. In some embodiments, a wetting layer is formed on the substrate. The wetting layer includes chromium, titanium, or combinations thereof

In some examples, the shadow mask is mounted on free-standing bridges and is subsequently placed in contact with the substrate. In some examples, one or more spacers may be used to place the shadow mask on the substrate. Examples of one or more spacers include, but are not limited to, dielectric microspheres, thin polymeric sheets, silicon nitride (SiNₓ) membranes, or combinations thereof.

At block 208, a material is deposited on the first surface of the substrate through the plurality of apertures of the shadow mask to form the pattern on the substrate. In some examples, the material includes metals, oxides, fluorides, sulphides, polymers, or combinations thereof. The material can be deposited on the substrate using any suitable deposition techniques. In some examples, the material is deposited on the substrate using physical vapor deposition (PVD), electronic beam physical vapor evaporation (EBPVD), sputter deposition, pulse laser ablation, chemical vapour deposition (CVD), or combinations thereof. In some embodiments, a plurality of layers of one or more materials are deposited on the substrate to form a multi-layered structure on the substrate.

At block 210, the shadow mask is removed from the substrate. At block 212, the removed shadow mask is cleaned by at least one solvent. In one example, ultrasonication of the shadow mask in the solvent is used to clean the shadow mask. Examples of the at least one solvent include, but are not limited to hydrochloric acid (HCl), water, ethanol, methanol, or combinations thereof. In some examples, the material includes a pre-deposited thin film of a dissolvable material to facilitate removal of deposited material from the shadow mask.

In one example, the polymeric sheet is a kapton sheet. In this example, the kapton sheet is heated to a temperature of about 200° C. to form the annealed sheet. Further, a pattern from a primary mask is transferred to the annealed sheet using laser micromachining to form a shadow mask having a plurality of apertures. The shadow mask is used to deposit variety of materials such as metals, oxides, fluorides, sulphides, polymers, or combinations thereof through the plurality of apertures. In one example, metals such as gold (Au) or aluminum (Al) are deposited on a substrate through the plurality of apertures. In this example, hydrochloric acid (HCl) is used to remove deposited material from the shadow mask.

At block 214, the cleaned shadow mask is reused for forming the pattern on another substrate. In some examples, the shadow mask is configured to be reused for at least about 2 times for forming the pattern on the substrate. In some examples, the shadow mask is configured to be reused for at least about 4 times for forming the pattern on the substrate. In some examples, the shadow mask is configured to be reused for at least about 6 timesfor forming the pattern on the substrate. In some examples, the shadow mask is configured to be reused for at least about 8 times for forming the pattern on the substrate. In some examples, the shadow mask is configured to be reused for at least about 10 times for forming the pattern on the substrate. In some examples, the shadow mask is configured to be reused for at least about 20 times for forming the pattern on the substrate.

FIG. 3 illustrates an example shadow mask 300 such as formed using the process of FIG. 1. The shadow mask 300 includes an annealed polymeric sheet 302 having a plurality of apertures (generally represented by reference numeral 304). The shadow mask 300 is used for depositing a material on a substrate through the plurality of apertures 304 and to form a desired pattern of the material on the substrate. In some examples, the annealed polymeric sheet 302 comprises polyimide, polythene, polytetrafluoroethylene (PTFE), or combinations thereof.

In some examples, the annealed polymeric sheet 302 has a thickness of about 12 μm to about 50 μm. Specific examples of the thickness include about 12 μm, about 15 μm, about 20 μm, about 25 μm, about 30 μm, about 35 μm, about 40 μm, about 45 μm, about 50 μm, and ranges between any two of these values (including endpoints).

The plurality of apertures 304 can generally be of any shape. Example shapes of the apertures 304 include circular, square, rectangular, complex, or combinations thereof In some examples, the plurality of apertures 304 have a radius of curvature of about 0.5 μm to about 1 μm. Specific examples of the radius of curvature include about 0.5 μm, about 0.6 μm, about 0.7 μm, about 0.8 μm, about 0.9 μm, about 1 μm, and ranges between any two of these values (including endpoints).

In some examples, the plurality of apertures 304 have a diameter of about 800 nanometes (nm) to about 5 μm. Specific examples of the diameter of the apertures 304 include about 800 nm, about 1 μm, about 2 μm, about 3 μm, about 4 μm, about 5 μm, and ranges between any two of these values (including endpoints).

As described above, one or materials may be deposited on a substrate through the plurality of apertures 304. In some examples, the apertures 304 are used for selective deposition of material to form micro and nanostructures on the substrate. In some examples, the substrate is formed of glass, silicon, aluminum, steel, silicon dioxide (SiO₂), aluminum oxide (Al₂O₃), zinc sulfide (ZnS), zinc selenide (ZnSe), teflon, or combinations thereof. In some examples, the material includes metals, oxides, fluorides, sulphides, polymers, or combinations thereof. In some examples, the shadow mask 300 has an absorption coefficient (α) greater than about 50×10³cm⁻¹ at a wavelength of about 248 nm.

In some embodiments, an assembly is provided. The assembly includes a substrate and a shadow mask disposed on a first surface of the substrate. The shadow mask includes an annealed polymeric sheet having a plurality of apertures formed in the annealed polymeric sheet. In some examples, the annealed polymeric sheet is formed of polyimide, polythene, polytetrafluoroethylene (PTFE), or combinations thereof. In this embodiment, the shadow mask is configured to deposit a material on the substrate through the plurality of apertures to form a desired pattern of the material on the substrate. In some examples, the substrate is formed of glass, silicon, aluminum, steel, silicon dioxide (SiO₂), aluminum oxide (Al203), zinc sulfide (ZnS), zinc selenide (ZnSe), Teflon. In some examples, the material includes metals, oxides, fluorides, sulphides, polymers, or combinations thereof.

In some embodiments an assembly is provided. The assembly includes a substrate and a shadow mask disposed on a first surface of the substrate. The shadow mask includes an annealed polymeric sheet having a plurality of apertures formed in the annealed polymeric sheet and a material disposed on the shadow mask. The shadow mask is configured to deposit the material on the substrate through the plurality of apertures to form a desired pattern of the material on the substrate.

### EXAMPLES

The present invention will be described below in further detail with examples and comparative examples thereof, but it is noted that the present invention is by no means intended to be limited to these examples.

### Example 1

### Formation of a Shadow Mask

In this example, a re-useable shadow mask was formed for deposition of materials through features having sizes in micrometer range. The shadow mask was formed by dry laser micromachining process.

Here, a polyimide sheet having a thickness of about 12 μm was annealed by heating the polyimide sheet to a temperature of about 200° C. to form an annealed polyimide sheet. The heating of the polyimide sheet removed any residual stresses and parallel deformation of the sheet. The annealed polyimide sheet had shrinkage of less than about 1% for temperatures greater than about 200° C.

Further, a pattern from a primary mask was transferred to the annealed polymeric sheet using excimer laser micromachining to form the shadow mask. A primary binary having the desired features at length scales ‘L’ was used to form the features on the shadow mask and demagnification optics was used to provide a demagnification ratio of N (for example, 5, 10, 20 times) for the laser micromachining set up.

The pattern included a plurality of apertures that were machined through the polyimide sheet. Here, the surface of the annealed polyimide sheet was laser machined using a laser emitting radiation with a wavelength of one of about 356 nanometers (nm), about 337 nm, about 308 nm, about 266 nm, about 248 nm, and about 193 nm. The surface of the annealed polymericpolyimide sheet was laser machined with about 25 laser pulses. Moreover, the laser pulses had a frequency of about 1 Hertz (Hz) to about 100 Hz. The diameter of the apertures formed on the sheet was about 3 μm.

The shadow mask formed of the annealed polyimide sheet was mounted on a free-standing bridge. The shadow mask was connected with the substrate using spacers. Here, dielectric microspheres were used as the spacers. The substrate and the shadow mask along with the spacers were clamped together and the assembly was loaded into an evaporator for deposition through apertures of the shadow mask.

Here, the apertures in the shadow mask facilitated selective deposition of the material to form a pattern on the substrate. The material was deposited on the substrate by physical vapour deposition method. Here, the materials used are gold, aluminum or combinations thereof. The shadow mask was subsequently removed from the surface of the substrate and was cleaned using hydrochloric acid (HCl) in an ultrasonicator to remove the traces of material deposited on the shadow mask.

### Example 2

### Characterization of the Shadow Mask Formed in Example 1

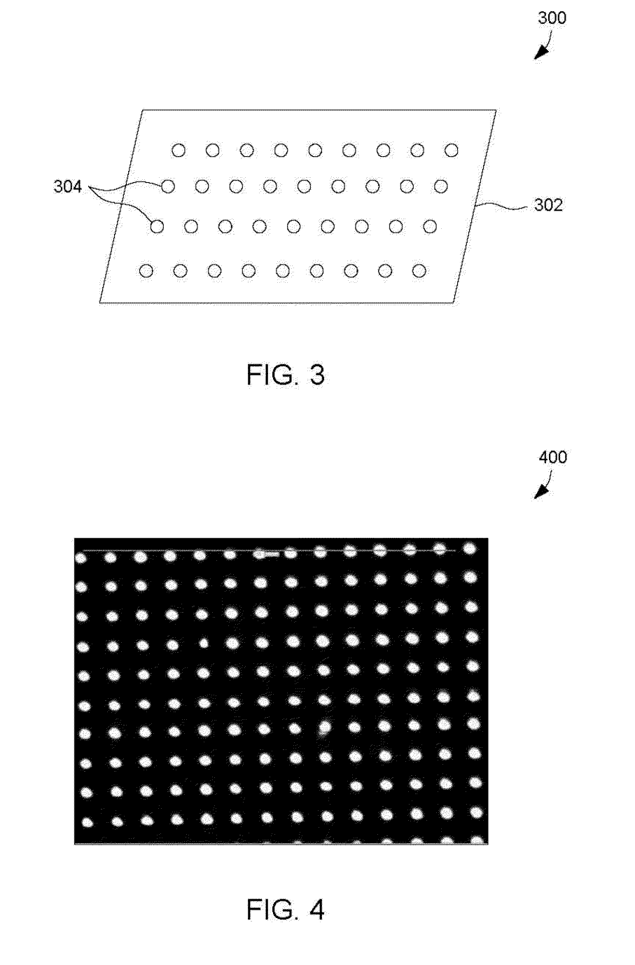

The shadow mask formed in Example 1 was characterized using transmission optical microscopy. FIG. 4 illustrates a transmission image 400 of the shadow mask. As can be seen from the image 400, an array of apertures was formed on about 8 μm square lattice in a polyimide film having a thickness of about 12 μm. The diameter of the apertures was about 3 μm.

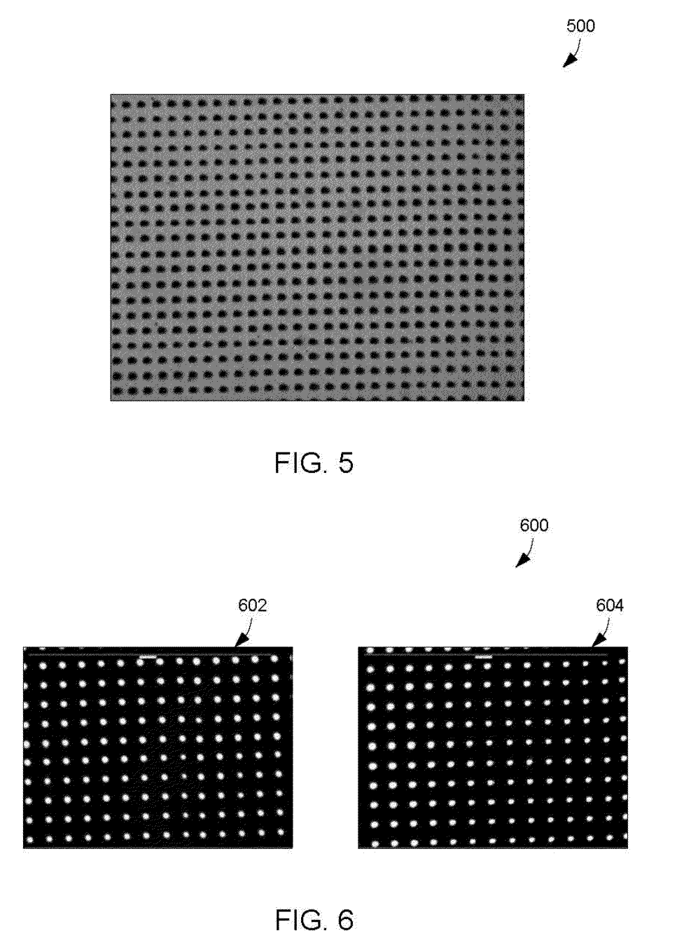

FIG. 5 illustrates an optical microscope transmission image 500 of a substrate material deposited through the shadow mask of Example 1. Here, the image 500 is a transmission optical image of a 3 μm gold disk having about 100 nm gold film deposited through the shadow mask. As can be seen, transmission was observed from the unshadowed region.

### Example 3

### Reuse Data of Patterning using the Shadow Mask of Example 1

The shadow mask described above was used a number of times for forming patterns on any given substrate. After each use, the shadow mask was removed from the substrate and was cleaned using a solvent. Here, the shadow mask was cleaned using hydrochloric acid (HCl) in an ultrasonicator to remove the material deposited on the mask. Further, the cleaned shadow masks were reused a number of times for forming the pattern on substrates.

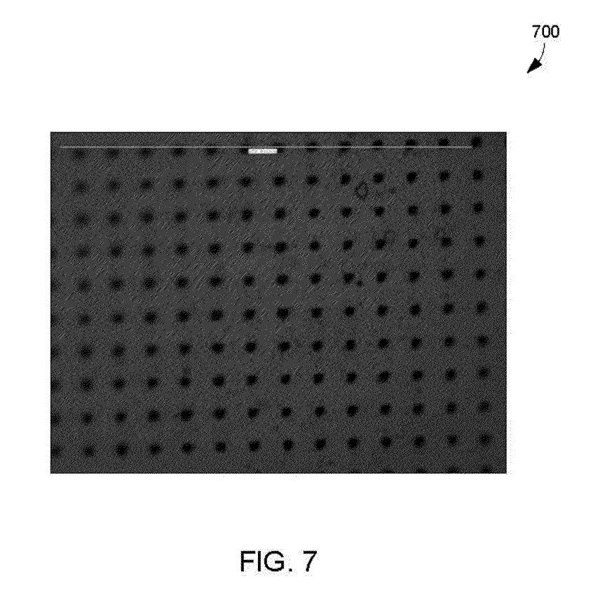

FIG. 6 illustrates transmission optical microscope images 600 of the shadow mask after first and fourth use of forming the pattern on the substrate. Here, image 602 is the image of the shadows mask after the first use and image 604 is image of the shadow mask after the fourth use of forming the pattern on the substrate. As can be seen from the images 602 and 604, the shadow masks were observed to be substantially the same even after the fourth use of the shadow mask for patterning. FIG. 7 is example image 700 of reflectance through the shadow mask after fourth use of forming the pattern on substrate. The reflectance pattern shows that the mask was substantially the same even after the fourth use indicating that the shadow mask can be used multiple times for depositing materials.

### Example 4

### Comparative Results for Parameters of the Shadow Mask Formed Using the Present Technique and Formed using the Conventional Techniques

The parameters for shadow mask formed using the present technique were compared with corresponding parameters for shadow masks formed using conventional techniques such as photo lithography, electron-beam (e-beam) lithography and using focused ion beam. A comparison of the parameters are provided in Table 1.

TABLE 1

| | Present | Photo- | E-beam | Focusedion |
|---|---|---|---|---|
| Methods/Parameters | technique | lithography | lithography | beam |
| Feature size (microns) | 100 μm-1 μm | 100 μm-0.3 μm | 100 μm-0.05 μm | 0.015 μm |
| Features with sharp | Good | Good | Very good | Very good |
| angles | | | | |
| Coverage area size | Few cm² | Few cm² | 100 m × 100 m | 100 m × 100 m |
| Dry/wet processing | Dry | Wet | Wet | Wet |
| Processing material | Low | High | High | Very High |
| cost | | | | |
| Machining rate | High | High | Low | Low |
| Minimum steps | Laser | Photo-resist | electron-resist | Metal coating, |
| required | machining, | coating, | coating, exposure, | exposure |
| | deposition | exposure, | development, | |
| | | development, | metallization, | |
| | | metallization, | liftoff | |
| | | liftoff | | |

As can be seen, the present technique provides methods for fabricating high quality shadow masks with features having sizes in micrometer range. The size of features can be about 1 μm to about 100 μm. The features formed in the shadow masks using the present technique are sharp with good reproducibility as compared to those formed using conventional techniques.

The shadow masks formed using present technique can be used for large area patterning of thin metallic films using a single step process. The materials used for the shadow mask have less than about 1% shrinkage at deposition temperature of about 1200° C. The present technique can be used to make additional patterns on pre-existing structured surfaces. For example, the present technique can be used to form an absorbing plasmonic coating over a photo-voltaic detector array or camera focal plan array (FPA). Moreover, the technique can also be used for etching and implantation of sub micrometer structures using ion beam and plasma techniques.

The shadow masks formed using the present technique may be used for fabrication of variety of components such as integrated circuits, microelectromechanical systems (MEMS), microfluidic devices, photonic communication devices andmetamaterial structures for infra-red materials.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims.

The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present.

For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “ a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “ a system having at least one of A, B, or C” would include but not be limited to systems that have A alone, B alone, C alone, A and B together, A and C together, B and C together, and/or A, B, and C together, etc.).

It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed herein also encompass any and all possible sub ranges and combinations of sub ranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc.

As will also be understood by one skilled in the art all language such as ^{“}up to,” “at least,” “greater than,” “less than,” and the like include the number recited and refer to ranges which can be subsequently broken down into sub ranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A method of forming a shadow mask, the method comprising:
annealing at least one polymeric sheet to form at least one annealed polymeric sheet; and transferring a pattern from a primary mask to the annealed polymeric sheet using laser micromachining to form the shadow mask.

2. The method of claim 1, wherein annealing the polymeric sheet comprises heating the sheet to a temperature of about 100 centigrade (° C.) to about 200° C.

3. The method of claim 1, wherein transferring the pattern comprises forming a plurality of features through the annealed polymeric sheet.

4. The method of claim 3, wherein forming the plurality of features comprises forming one or more apertures that are substantially circular, square, rectangular, or combinations thereof.

5. The method of claim 4, wherein forming the plurality of features comprises forming features with a radius of curvature of about 0.5 micrometers (μm) to about 1 μm.

6. The method of claim 4, wherein forming the plurality of features comprises forming the features with a size of about 1 μm to about 100 μm.

7. The method of claim 1, wherein annealing the at least one polymeric sheet comprises annealing a polyimide sheet.

8. The method of claim 1, wherein annealing the at least one polymeric sheet comprises annealing a sheet of polyethylene, polytetrafluoroethylene (PTFE), or combinations thereof.

9. The method of claim 1, wherein transferring the pattern comprises laser machining the surface of the annealed polymeric sheet with a laser emitting radiation with a wavelength of one of about 356 nanometers (nm), about 337 nm, about 308 nm, about 266 nm, about 248 nm, and about 193 nm.

10. A method of forming a pattern on a substrate, the method comprising:
transferring a pattern from a primary mask to an annealed polymeric sheet using laser micromachining to form a shadow mask having a plurality of apertures; mounting the shadow mask on a first surface of the substrate; and depositing a material on the first surface of the substrate through the plurality of apertures of the shadow mask to form the pattern on the substrate.

11. The method of claim 10, wherein transferring the pattern comprises transferring the pattern to a polyimide sheet.

12. The method of claim 10, further comprising exposing a polymeric sheet to heat to form the annealed polymeric sheet before the transferring step.

13. The method of claim 10, wherein depositing the material on the substrate comprises depositing the material using physical vapor deposition (PVD), electronic beam physical vapor evaporation (EBPVD), sputter deposition, pulse laser ablation, chemical vapour deposition (CVD), or combinations thereof.

14. The method of claim 10, further comprising after the depositing step:
removing the shadow mask from the substrate; cleaning the removed shadow mask by at least one solvent; and reusing the cleaned shadow mask for forming the pattern on another substrate.

15. The method of claim 10, wherein mounting the shadow mask on the substrate comprises mounting the shadow mask on the substrate formed of glass, silicon, aluminum, steel, silicon dioxide (SiO₂), aluminum oxide (Al₂O₃), zinc sulfide (ZnS), zinc selenide (ZnSe), teflon, or combinations thereof.

16. The method of claim 10, further comprising forming a wetting layer on the substrate prior to depositing the material on the substrate.

17. A shadow mask comprising: an annealed polymeric sheet; and a plurality of apertures formed in the annealed polymeric sheet to deposit a material on a substrate through the plurality of apertures and to form a desired pattern of the material on the substrate.

18. The shadow mask of claim 17, wherein the annealed polymeric sheet comprises polyimide, polythene, polytetrafluoroethylene (PTFE), or combinations thereof.

19. The shadow mask of claim 17, wherein the annealed polymeric sheet has a thickness of about 12 μm to about 50 μm.

20. The shadow mask of claim 17, wherein the substrate comprises glass, silicon, aluminum, steel, silicon dioxide (SiO₂), aluminum oxide (Al₂O₃), zinc sulfide (ZnS), zinc selenide (ZnSe), teflon, or combinations thereof

21. The shadow mask of claim 17, wherein the material comprises metals, oxides, fluorides, sulphides, polymers, or combinations thereof.

22. An assembly, comprising: a substrate; a shadow mask disposed on a first surface of the substrate, wherein the shadow mask comprises an annealed polymeric sheet having a plurality of apertures formed in the annealed polymeric sheet.

23. The assembly of claim 22, wherein the shadow mask is configured to deposit a material on the substrate through the plurality of apertures to form a desired pattern of the material on the substrate.

24. The assembly of claim 22, wherein the annealed polymericsheet comprises polyimide, polythene, polytetrafluoroethylene (PTFE), or combinations thereof.

25. The assembly of claim 22, wherein the material comprises metals, oxides, fluorides, sulphides, polymers, or combinations thereof.
